(19) United States
(12) Patent Application Publication
(10) Pub. No.: US 2026/0119758 A1
(43) Pub. Date: Apr. 30, 2026

(54) Unified Mesh Vertex Indexing Method for High-Fidelity Parallel Full-Core Fast Reactor Simulation

(71) Applicant: University of Science and Technology Beijing, Beijing (CN)

(72) Inventors: Genshen CHU, Beijing (CN); Qi WANG, Beijing (CN); Lingyu DONG, Beijing (CN); Tingting CHEN, Beijing (CN); Jiachen WU, Beijing (CN); Fangxiao ZHANG, Beijing (CN); Dandan CHEN, Beijing (CN); Changjun HU, Beijing (CN)

(21) Appl. No.: 19/012,130

(22) Filed: Jan. 7, 2025

(30) Foreign Application Priority Data
May 30, 2024 (CN) 202410686890.X

(51) Int. Cl. G06F 30/28

(52) U.S. Cl. CPC G06F 30/28

(57) ABSTRACT

A unified mesh vertex indexing method for high-fidelity parallel full-core fast reactor simulation belongs to the fields of high performance computing and numerical simulation. Firstly, a constant is defined and a message passing interface (MPI) is initialized; processors then generate local hash tables concurrently to obtain local vertex numbers; next, a processor 0 generates a global hash table by MPI_Send( ) and MPI_Recv( ) functions, processes a conflict, and finally obtains global vertex numbers, thus building indexes. Local numbering and global numbering of mesh vertexes are realized with the hash table. Parallel processing of vertex numbering tasks of the processors is realized through the MPI. An innovative global vertex numbering method is provided for the processors. Large-scale parallel efficiency is improved. The research and development of large-scale high-fidelity numerical simulation software for a thermal fluid can be facilitated.

### CROSS REFERENCE TO RELATED APPLICATION

This patent application claims the benefit and priority of Chinese Patent Application No. 202410686890X, filed with the China National Intellectual Property Administration on May 30, 2024, the disclosure of which is incorporated by reference herein in its entirety as part of the present application.

### TECHNICAL FIELD

The present disclosure relates to the fields of high performance computing and numerical simulation, and in particular, to a unified mesh vertex indexing method for high-fidelity parallel full-core fast reactor simulation.

### BACKGROUND

A fast neutron reactor is the main reactor type of generation IV advanced nuclear energy systems in the world. It has the advantages of good safety, less waste, and the like. With increasing requirements on the safety and economic efficiency of a nuclear energy system, large-scale simulation software with high accuracy and high efficiency is receiving increasing attention, especially high-fidelity thermal fluid calculation simulation software with independent intellectual property rights, which can help with power increase and service life-prolonging of a reactor in China, assembly design and improvement, safety assessment and analysis, and new reactor design and development, and has strong engineering requirements and practical significance. Traditional numerical simulation methods for a thermal fluid, such as a system method and a sub-channel method, can be only capable of macro-scale overall flow field analysis, and fail to capture micro-scale detail information within the fluid. Therefore, in order to meet the requirements of more detailed description and high-accuracy simulation on flow field behaviors, Computational Fluid Dynamics (CFD), especially CFD computing of Direct Numerical Simulation (DNS) and Large Eddy Simulation (LES), usually needs to be adopted. However, such methods require a large number of meshes and a huge quantity of computations, have extremely high requirements on computing power and storage, and must rely on super computers and large-scale parallel computing. This means that tasks must be scheduled to different processor cores for parallel processing such that computing resources are fully utilized, thereby realizing efficient numerical simulation.

In a general CFD computing method, a process is clearly divided into preprocessing and main solving parts (as shown in FIG. 1). However, for high-fidelity DNS/LES simulation of fast reactor cores for full scale, due to a large number of meshes, the time taken by full-core meshing and full-core mesh file output of the preprocessing is unacceptable, and the mass storage needed by meshes is also a great challenge. Full-core mesh reading during main solving and full-core solution variable mesh output after the completion of solving are also difficulties that need to be overcome. In order to solve these difficult problems, researchers proposed a topology replication and mesh stitching technique based on the isomorphism of a reactor to realize full-core mesh model construction adaptive to high-fidelity simulation of a reactor (as shown in FIG. 2) according to repeated and fixed structural information in axial and radial directions of the full-core of the reactor (Dong L, MiaoX, Meng X, et al. Challenges in high-fidelity thermal-hydraulic simulation of SFR cores: Insights and PACA-S 4FR solutions[J]. Nuclear Engineering and Design, 2024, 416:112755), and thus proposed a distributed computing technique for a thermal fluid based on the isomorphism of the reactor. Mapping from a minimum basic elementary section to the full-core and efficiency computation of the thermal fluid of the reactor are realized. Mesh generation is set at the main solving stage. This method can effectively ameliorate problems such as insufficient computing resources and memory and too long time taken in a large-scale simulation process.

The core of large-scale parallel tasks is mapping from a large number of meshes to different processor cores, and communication and collaboration between different processors (also between different mesh tasks). In order to guarantee the communication efficiency between processes during solving, processors need a unified mesh vertex indexing method. A unique global vertex is endowed to the same physical vertex in different processors. The mesh vertex indexing technique is the basis of parallel simulation, which has a direct bearing on the computing efficiency. A traditional thermal fluid simulation method includes: reading a whole mesh file at a preprocessing stage, firstly performing global vertex numbering to build indexes, and then performing parallel domain decomposition to average distribute mesh vertexes to processors, thereby guaranteeing load balancing. However, in distributed computing for a thermal fluid based on the isomorphism of a reactor, processors read their respective segmental files. Full-core assemblies are formed by replication and translation without domain decomposition, but the processors lack global information, which may cause a problem that different numbers might be endowed to the same physical vertex in different processors. Therefore, the key is how to guarantee the uniqueness of the entire mesh vertex index numbering. Since an existing global vertex numbering method is based on an entire mesh file rather than on segmental files, does not need to perform the task of entire mesh generation, does not lack global information of mesh vertexes, and cannot meet current requirements, how to endow a unique global vertex number to a mesh vertex in the absence of the global information so as to establish mesh vertex indexes has become an urgent problem to be solved. Given this, the present disclosure provides a unified mesh vertex indexing method for high-fidelity parallel full-core fast reactor simulation.

### SUMMARY

An objective of the present disclosure provides a unified mesh vertex indexing method for high-fidelity parallel full-core fast reactor simulation to solve the problem that a unified mesh vertex index between different mesh segments cannot be established in distributed computing of a thermal fluid based on the isomorphism of a full-core of a reactor mentioned in the background.

To achieve the above objective, the present disclosure adopts the following technical solutions:

A unified mesh vertex indexing method for high-fidelity parallel full-core fast reactor simulation specifically includes the following steps:
S1, generation of local hash tables: generating, by processors, the local hash tables concurrently using mesh information in segments thereof, traversing each vertex in the processors, generating hash values according to vertex coordinates, determining local vertex numbers, and recording processor numbers;
S2, array passing: sending the hash values, the local vertex numbers, and the processor numbers obtained in S1 to a processor 0 in a form of an array;
S3, preliminary generation of a global hash table: receiving, by the processor 0, vertex information from the processors, and storing vertexes having a same hash value into a same node, thereby generating the global hash table;
S4, conflict processing: traversing the global hash table generated in S3, and performing conflict processing on each node having more than 2 members: comparing key values of vertexes; if the key values are identical, skipping performing processing; if the key values are different, indicating that a conflict occurs, and finding a new hash value;
S5, number postback: passing vertex information having a same processor number back to respective processors according to the processor numbers for the vertexes, and gathering vertex information of segments of a full-core; and
S6, vertex mapping: after the processors receive the vertex information passed back, sorting local information of the vertexes in an ascending order, and generating mapped data until the segments of the full-core have completed global vertex numbering tasks in the respective processors, thus completing index building.

Preferably, step S1 specifically includes:
S1.1, initializing a hash table, and establishing the local hash table according to a number of vertexes in the processors, wherein a size of the established hash table is SIZE, and each element in the table is a null pointer; and
S1.2, traversing each vertex in the processors, generating the hash values according to the vertex coordinates, determining the local vertex numbers according to an order of traversing the vertexes, and recording the processor numbers, followed by inserting nodes into the hash table.

Preferably, step S4 specifically includes:
S4.1, sequentially constituting, by the processor 0, nodes with the vertex information sent from other processors, and preliminarily inserting the nodes into the global hash table according to the hash values; and
S4.2, traversing the global hash table, and performing conflict processing on each node having more than 2 members: comparing the key values of the vertexes; if the key values are identical, indicating that the vertexes are the same vertex from different processors and skipping performing processing; if the key values are different, indicating that a conflict occurs, finding a new hash value for the vertex, and reinserting the new hash value into the global hash table, where
after the completion of traversal, each physical vertex has a unique hash value, and the hash values of the vertexes are global vertex numbers.

Compared with the prior art, the present disclosure provides a unified mesh vertex indexing method for high-fidelity parallel full-core fast reactor simulation, which has the following beneficial effects.
(1) A simulation scale is expanded, and this method is applicable to full-core meshes. Using a reactor isomorphism principle and distributed parallel computing, global numbering can be performed on physical vertexes of meshes on the basis that processors lack global vertex information, thus building indexes.
(2) This method is applicable to high-fidelity thermal fluid simulation calculation software. The global vertex numbers obtained by this method can be convenient for subsequent communication between the processors. A higher-order accuracy method (e.g., a spectral element method) can be used, and the simulation accuracy can be improved.
(3) A thermal fluid computation speed is effectively increased; a storage cost is reduced; and the problems of insufficient memory in a computation process are ameliorated. The processors do not need to read an entire full-core file, and read segmental files instead. The full core is assembled by replication and translation.
(4) A degree of parallelism of computations is increased. By applying parallel hash tables, the processors complete preliminary numbering synchronously such that a degree of parallelism of tasks is increased.

In conclusion, the present disclosure provides a unified mesh vertex indexing method for high-fidelity parallel full-core fast reactor simulation With this method, each processor can realize global vertex numbering on the basis of only segmental information existing and build a unique mesh vertex index. The gap in the field is made up, and the research and development of the high-fidelity thermal fluid calculation simulation software with independent intellectual property rights are promoted.

### BRIEF DESCRIPTION OF THE DRAWINGS

FIG. 1 is a flowchart of traditional CFD solving proposed in the background of the present disclosure, which is divided into preprocessing and main solving parts. Meshing is performed at the preprocessing part and used as inputs to the main solving part, thereby completing the solving of equations.

FIG. 2 is a schematic diagram of a topology replication and mesh stitching technique based on the isomorphism of a reactor proposed in the background of the present disclosure, showing a basic principle of full-core mesh model construction adaptive to the high-fidelity simulation of a reactor. Full-core meshes can be generated from basic unit mesh models of components by axial and radial translations.

FIG. 3 is an overall flowchart of a unified mesh vertex indexing method for high-fidelity parallel full-core fast reactor simulation provided in Example 1 of the present disclosure. A basic flow includes: at the beginning, defining a constant and initializing a message passing interface (MPI); then generating local hash tables by processors concurrently to obtain local vertex numbers; next, generating, by a processor 0, a global hash table by MPI_Send( ) and MPI_Recv( ) functions, processing a conflict, and finally obtaining global vertex numbers, thus building indexes.

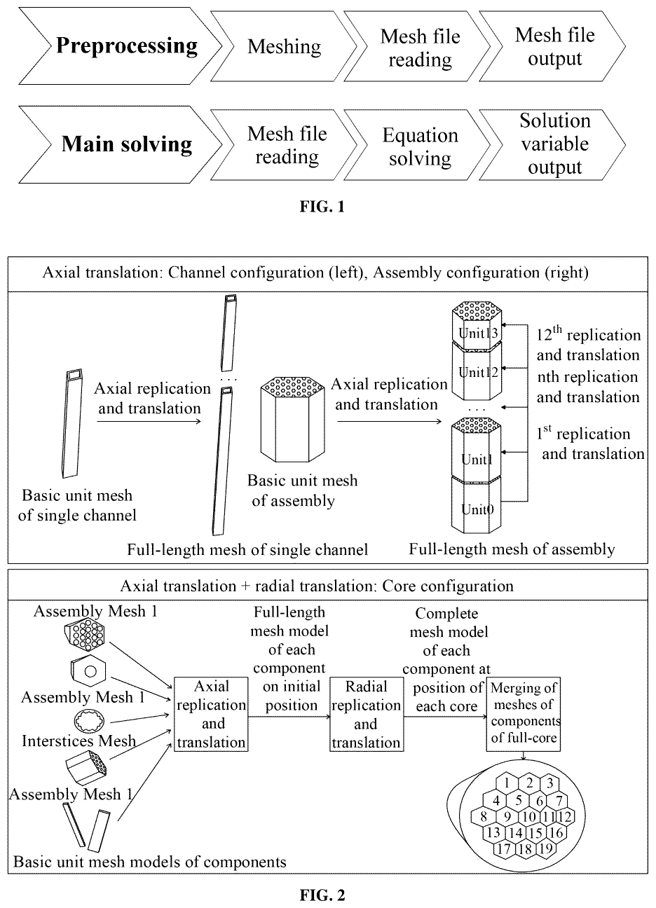

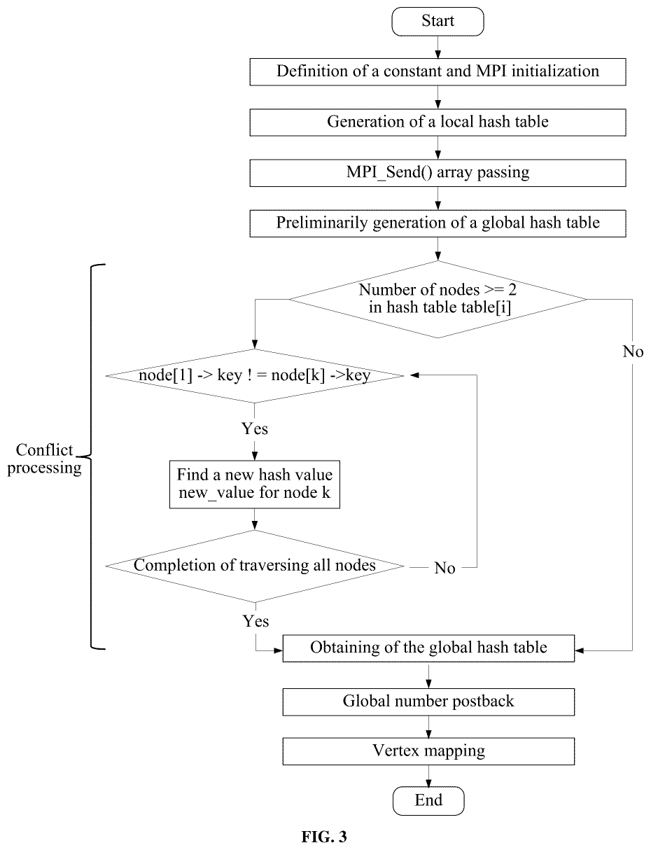

### DETAILED DESCRIPTION OF THE EMBODIMENTS

The technical solutions of the embodiments of the present disclosure are clearly and completely described below with reference to the accompanying drawings. Apparently, the described embodiments are merely a part rather than all of the embodiments of the present disclosure.

The present disclosure is oriented to high-fidelity distributed computing of a thermal fluid of a full-core of a fast neutron reactor and aims to provide a unified mesh vertex indexing method for high-fidelity parallel full-core fast reactor simulation based on processors only having their respective segmental mesh files, to build mesh vertex indexes. Specifically, local numbering and global numbering of mesh vertexes are realized with a hash table. Parallel processing of vertex numbering tasks of the processors is realized through the MPI. An innovative global vertex numbering method is provided for the processors. Large-scale parallel efficiency is improved. The research and development of large-scale high-fidelity numerical simulation software for a thermal fluid can be facilitated.

The vertex numbering task can be generally executed using a multi-dimensional segmental sorting method based on specific features of a graphical or topological structure. When separating elementary sections after replication and translation, due to the lack of global information, local vertex numbering can be performed on the elementary sections in the processors. Parallel execution of tasks is realized by the MPI. A unique number is endowed to a vertex by the hash table. Vertex information of other processors is sent to processor 0 afterward. A conflict might be present during processing. A global hash table is generated. Thus, a unique global number is provided for a vertex.

The unified mesh vertex indexing method for high-fidelity parallel full-core fast reactor simulation provided in the present disclosure is described below in conjunction with a specific example. Specific contents are as follows.

### Example 1

It is assumed that a segment stored in each processor at present includes num_of_vertex vertexes, the total number of processors is N, and the size of a hash table is SIZE=number_of_vertex*2. In simulation computing, N processes are created using an MPI, and each process represents a processor. num_of_vertex and SIZE are positive integers, and N is a positive integer greater than or equal to 2. It needs to be noted that due to the segmental storage of a full-core of a reactor, a same physical vertex might be present in different processors, which needs to be determined and is endowed with a same global number.

### 1. Important Data Structure (C++ Description)

(1) Data structure of a node:
typedef struct Node{
float key[3];
int value;
int processorId;
int localId;
struct Node*next;
}Node;

where key represents three-dimensional coordinates of a vertex; value is a generated hash value; processorId represents a processor number for a current vertex; localId represents a local number of the current vertex; and next is a pointer pointing to the next node.

### (2) Data Structure of a Hash Table

typedef struct HashMap{
int size;
Node**table;
}HashMap;

where size represents the size of the hash table; and table represents a two-dimensional array, where each element is a pointer pointing to the Node structure.

### 2. Specific Steps (as Shown in FIG. 3)

### Generation of a Local Hash Table:

(1) A hash table is initialized, and the hash table hashMap is established according to the number num_of_vertex of vertexes in the processors, where the size of the established hash table is SIZE, and each element in the table is a null pointer NULL.
(2) Each vertex in the processors is traversed; a hash value is generated according to coordinates of the vertex (x,y,z); a local vertex number localId thereof is determined according to an order of traversing the vertexes (a local number of an ith vertex traversed is i), and the processors are numbered as processorId, and a node is inserted into the hash table.

An array is passed and a global hash table is preliminarily generated:
(1) The hash table is traversed, and vertex information (key, value, localId, processorId) corresponding to nodes is sequentially stored into arrays array_key, array_value, array_localId, and array_processorId.
(2) The above-mentioned arrays are sent to processor 0 using MPI_Send( ) function. The processor 0 receives arrays sent from the processors.

### Conflict Processing:

(1) The processor 0 sequentially constitutes the vertex information sent from other processors into nodes which are preliminarily inserted into the global hash table according to values.
(2) The global hash table is traversed. If there are 2 or more nodes in table[i], conflict processing is performed on these nodes. Assuming that there are j nodes in table[i], the key values of nodes 2, 3, . . . , j are compared with the key value of node 1. If the key values of node 1 and k (2<=k<=j) are identical, it indicates that they are the same physical vertex in different processors, and no processing is performed. On the contrary, it indicates that a conflict occurs, and a new hash value new_value is found for the vertex k and reinserted into the global hash table. A pseudocode of a method of building global mesh vertex indexes based on parallel hash tables in large-scale high-fidelity full-core fast reactor simulation is shown below.

Algorithm 1 Global Hash Table Generation and Conflict Processing Algorithm

Input: receivedKey, receivedValue, receivedLocalId, receivedProcessorId, numprocs
Output: hashMap

| | |
|---|---|
| 1 | function INSERT(hashMap, receivedKey, received Value, receivedLocalId, receivedProcessorId) |
| 2 | index = receivedValue |
| 3 | //obtain a first node corresponding to receivedValue |
| 4 | node = hashMap → table[index] |
| 5 | if (node = NULL) then |
| 6 | The node is the first node of table[index]. |
| 7 | else |
| 8 | Find a position to be inserted with a node |
| 9 | Insert a new node to the position |
| 10 | end if |
| 11 | end function |
| 12 | for i = 0 to (numprocs − 1) * 500 ) do |
| 13 | // constitute received data into a node and insert the node into the global hash table hashMap |
| 14 | insert(hashMap, receivedKey[i], receivedValue[i], receivedProcessorId[i], receivedLocalId[i]) |
| 15 | end for |
| 16 | for I= 0 t₀hashMap-> size( ) do |
| 17 | count = a number of nodes in table[i] |
| 18 | if count > 2 then store all nodes in table[i] |
| 19 | else not process |
| 20 | end if |
| 21 | for j = 1 to count do |
| 22 | Compare with the coordinates of a first vertex |
| 23 | if the comparison result is the same, then not process |
| 24 | else find a new hash value new value for the node and reinsert the node into the global hash table |
| | hashMap |
| 25 | end if |
| 26 | end for |
| 27 | end for |

(3) After the completion of traversal, each physical vertex has a unique hash value, and the hash values of the vertexes are global vertex numbers, globalId=value.

### Number Postback:

(1) N for loops are performed such that the node information (global vertex numbers, local vertex numbers) having the same processor number in the global hash table is stored into the arrays array_globalId and array_localId.
(2) The arrays array_globalId and array_localId are sent back to the corresponding processors using the MPI_send( ) function in the loops.

### Vertex Mapping:

Other processors receive the data from the processor 0, and mapping from the local vertex numbers to the global vertex numbers global_numbering[localId]=globalId is generated. Index building thus is completed.

The foregoing are merely descriptions of preferred specific embodiments of the present disclosure, but the protection scope of the present disclosure is not limited thereto. Any equivalent replacement or modification made within a technical scope of the present disclosure by a person skilled in the art according to the technical solutions of the present disclosure and inventive concepts thereof shall fall within the protection scope of the disclosure.

What is claimed is:

1. A unified mesh vertex indexing method for high-fidelity parallel full-core fast reactor simulation, specifically comprising the following steps:
S1, generation of local hash tables: generating, by processors, the local hash tables concurrently using mesh information in segments thereof, traversing each vertex in the processors, generating hash values according to vertex coordinates, determining local vertex numbers, and recording processor numbers;
S2, array passing: sending the hash values, the local vertex numbers, and the processor numbers obtained in S1 to a processor 0 in a form of an array;
S3, preliminary generation of a global hash table: receiving, by the processor 0, vertex information from the processors, and storing vertexes having a same hash value into a same node, thereby generating the global hash table;
S4, conflict processing: traversing the global hash table generated in S3, and performing conflict processing on each node having more than 2 members, specifically comprising: comparing key values of vertexes; if the key values are identical, skipping performing processing; if the key values are different, indicating that a conflict occurs, and finding a new hash value;
S5, number postback: passing vertex information having a same processor number back to respective processors according to the processor numbers for the vertexes, and gathering vertex information of segments of a full-core; and
S6, vertex mapping: after the processors receive the vertex information passed back, sorting local information of the vertexes in an ascending order, and generating mapped data until the segments of the full-core have completed global vertex numbering tasks in the respective processors, thus completing index building.

2. The unified mesh vertex indexing method for high-fidelity parallel full-core fast reactor simulation according to claim 1, wherein S1 specifically comprises:
S1.1, initializing a hash table, and establishing the local hash table according to a number of vertexes in the processors, wherein a size of the established hash table is SIZE, and each element in the table is a null pointer; and
S1.2, traversing each vertex in the processors, generating the hash values according to the vertex coordinates, determining the local vertex numbers according to an order of traversing the vertexes, and numbering the processors, followed by inserting nodes into the hash table.

3. The unified mesh vertex indexing method for high-fidelity parallel full-core fast reactor simulation according to claim 1, wherein S4 specifically comprises:
S4.1, sequentially constituting, by the processor 0, nodes with the vertex information sent from other processors, and preliminarily inserting the nodes into the global hash table according to the hash values; and
S4.2, traversing the global hash table, and performing conflict processing on each node having more than 2 members, specifically comprising: comparing the key values of the vertexes;
if the key values are identical, indicating that the vertexes are the same vertex from different processors and skipping performing processing; if the key values are different, indicating that a conflict occurs, finding a new hash value for the vertex, and reinserting the new hash value into the global hash table, wherein
after the completion of traversal, each physical vertex has a unique hash value, and the hash values of the vertexes are global vertex numbers.
